(19) United States
(12) Patent Application Publication
(10) Pub. No.: US 2013/0088814 A1
(43) Pub. Date: Apr. 11, 2013

(54) ELECTRONIC APPARATUS USING FASTENING MEMBER PASSING THROUGH UPPER CASE OF ELECTRONIC APPARATUS AND MANUFACTURING METHOD THEREOF

(71) Applicants: JAE KWON JEONG, SUWON-SI (KR); HEUNG SOO PARK, NAMYANGJU-SI (KR)

(72) Inventors: JAE KWON JEONG, SUWON-SI (KR); HEUNG SOO PARK, NAMYANGJU-SI (KR)

(73) Assignees: HANHWA SOLUTION & CONSULTING CO., LTD, SEOUL (KR); INNOPIA TECHNOLOGIES, INC., SEONGNAM-SI (KR)

(21) Appl. No.: 13/287,349

(22) Filed: Nov. 2, 2011

(30) Foreign Application Priority Data
Oct. 6, 2011 (KR) 10-2011-0101865

(51) Int. Cl. H05K 5/00

(52) U.S. Cl. 361/679.01; 174/50

(57) ABSTRACT

An electronic apparatus and a manufacturing method thereof are provided. An upper case to protect an electronic circuit board is disposed on an upper part of a lower case to protect the electronic circuit board. A fastening member is passed through a hole formed at the upper case and fastened to a connection portion formed at the lower case. Accordingly, the upper case and the lower case are connected to each other. A cover is attached to an upper surface of the upper case to thereby cover the fastening member.

### CROSS-REFERENCE TO RELATED APPLICATION

This application claims the benefit of Korean Patent Application No. 10-2011-0101865, filed on Oct. 6, 2011, in the Korean Intellectual Property Office, the disclosure of which is incorporated herein by reference.

### BACKGROUND

1. Field of the Invention

The present invention relates to an electronic apparatus and a manufacturing method thereof, and more particularly, to an electronic apparatus using a fastening member passing through an upper case of the electronic apparatus to fasten the upper portion and a lower portion and a manufacturing method thereof.

2. Description of the Related Art

An electronic apparatus includes a case for protecting an electronic circuit board mounted inside.

Generally, the case is divided into an upper case and a lower case to facilitate a manufacturing process and reduce manufacturing cost. The upper case and the lower case are separately manufactured. After the electronic circuit board is placed in the lower case, the upper case and the lower case are connected.

In general, for assembly of the electronic apparatus, a connection member, for example a bolt, is inserted in a hole formed at the lower case and the connection member is fastened to a connection portion formed at the upper case. The reason for fastening the connection member through the lower case is to conceal a connection part of the connection member.

When the connection part is concealed, an appearance of the electronic apparatus may be improved. However, the manufacturing process may be complicated. Specifically, when a manufacturer fastens the connection member, the electronic apparatus being assembled needs to be turned over for insertion of the connection member into the electronic apparatus. While the electronic apparatus is turned over and assembled by the manufacturer, a trouble may occur in the electronic circuit board mounted inside. Also, a damage such as a scratch may be generated at an outside of the electronic apparatus including the upper case and the lower case. In such cases, loss cost imposed to the manufacturer may increase.

For more convenient assembly, an electronic apparatus may include a fastening portion provided to a lower end of an upper case and to an upper end of a lower case as disclosed in KR Patent Laid-open No. 10-201-0092907. A manufacturer may fit the fastening portion of the upper case to the fastening portion of the lower case by applying a predetermined force. However, according to such an assembly method, a connection force between the upper case and the lower case may be reduced in comparison to when a fastening member is used. Therefore, the upper case may be easily opened.

### SUMMARY

An aspect of the present invention provides an electronic apparatus using a fastening member that passes through a hole formed at an upper case of the electronic apparatus and is fastened to a connection portion formed at the lower case of the electronic apparatus.

Another aspect of the present invention provides a manufacturing method of an electronic apparatus in which an upper case and a lower case are connected by a fastening member that passes through a hole formed at the upper case and is fastened to a connection portion formed at the lower case.

According to an aspect of the present invention, there is provided an electronic apparatus including a lower case for protecting an electronic circuit board; an upper case for protecting the electronic circuit board; a fastening member to connect the upper case and the lower case to each other by passing through a hole formed at the upper case and being fastened to a connection portion of the lower case; and a cover attached to an upper surface of the upper case to cover the fastening member.

According to another aspect of the present invention, there is provided a manufacturing method for an electronic apparatus, the manufacturing method including disposing an upper case to protect an electronic circuit board on an upper part of a lower case to protect an electronic circuit board, connecting the upper case and the lower case to each other by passing a fastening member through a hole formed at the upper case and fastening the fastening member to a connection portion formed at the lower case, and attaching a cover to an upper surface of the upper case to thereby cover the fastening member.

The cover may include an empty space formed at a lower surface to receive a head of the fastening member.

The upper case may include a guide portion bent at a predetermined angle from a corner of the upper case toward a center of the upper case.

The cover may be slid into a groove formed by bending the guide portion and thereby attached to the upper surface of the upper case.

The cover may include a fastening protrusion formed on a lower surface. The upper case may include a fastening hole for insertion of the fastening protrusion.

The fastening member may be inserted in and slid along the fastening hole, thereby being fixed in the upper case.

The upper case may include an indicator disposed on a surface to output different shapes according to an electronic signal supplied from the electronic circuit board.

The cover may include an empty space or a transparent portion formed on a part of the cover.

The indicator may be exposed through the empty space or the transparent portion of the cover when the cover is attached to the upper case.

The cover may be plural.

The plurality of the covers may be attached to the upper surface of the upper case in a replaceable manner.

### EFFECT

According to embodiments of the present invention, an electronic apparatus uses a fastening member that passes through a hole formed at an upper case of the electronic apparatus and is fastened to a connection portion formed at the lower case of the electronic apparatus.

Additionally, according to embodiments of the present invention, a method of manufacturing the electronic apparatus in which the upper case and the lower case are connected by a fastening member that passes through the hole formed at the upper case and is fastened to the connection portion formed at the lower case.

The manufacturing method may simplify a manufacturing process of the electronic apparatus by using a bolt as the fastening member for secure assembly and, furthermore, inserting the bolt from the upper part of the electronic apparatus. As a result, inferiority rate of the electronic apparatus may be reduced.

Additionally, according to the manufacturing method, since a replaceable cover is attached to an upper surface of the upper case, design utility may be increased. The replaceable cover may easily vary appearance of the electronic apparatus at a low cost.

### BRIEF DESCRIPTION OF THE DRAWINGS

These and/or other aspects, features, and advantages of the invention will become apparent and more readily appreciated from the following description of exemplary embodiments, taken in conjunction with the accompanying drawings of which:

FIG. 1 is a diagram illustrating a structure of an electronic apparatus according to an embodiment of the present invention;

FIG. 2 is a diagram illustrating a connection system of a fastening member according to the embodiment of the present invention;

FIG. 3 is a diagram illustrating a guide of a cover according to the embodiment of the present invention;

FIG. 4 is a diagram illustrating a fastening protrusion of a cover according to the embodiment of the present invention; and

FIG. 5 is a flowchart illustrating a manufacture method of an electronic apparatus, according to an embodiment of the present invention.

### DETAILED DESCRIPTION

Reference will now be made in detail to exemplary embodiments of the present invention, examples of which are illustrated in the accompanying drawings, wherein like reference numerals refer to the like elements throughout. Exemplary embodiments are described below to explain the present invention by referring to the figures.

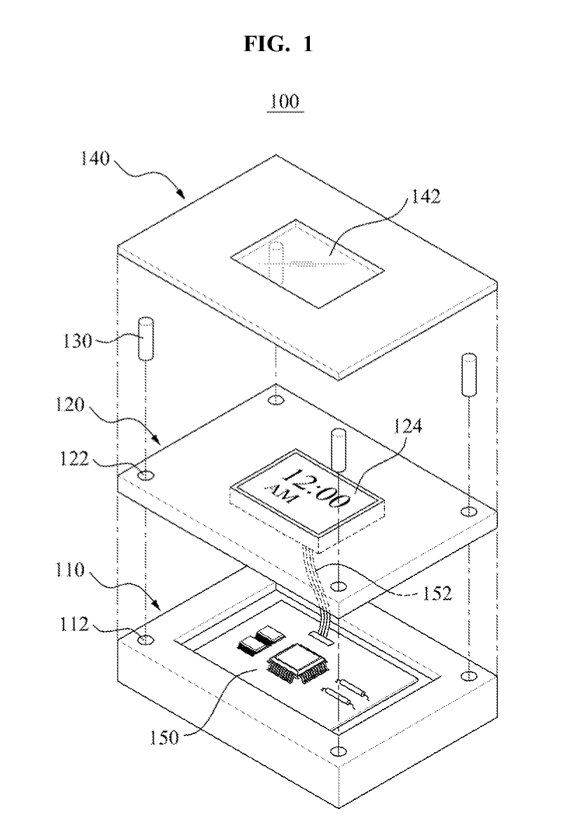

FIG. 1 is a diagram illustrating a structure of an electronic apparatus 100 according to an embodiment of the present invention.

The electronic apparatus 100 may include a lower case 110, an upper case 120, a fastening member 130, a cover 140, and an electronic circuit board 150.

The lower case 110 and the upper case 120 may protect the electronic circuit board 150. The electronic circuit board 150 may be disposed in an empty space defined in the lower case 110.

A connection portion 112 may be formed at an upper surface of the lower case 110.

A hole 122 is formed through a surface of the upper case 120.

The fastening member 130 may pass through the hole 122 formed at the upper case 120 and be fastened to the connection portion 112 of the lower case 110. Accordingly, the upper case 120 and the lower case 130 are connected to each other.

After the upper case 120 and the lower case 110 are connected, the cover 140 may be attached to an upper surface of the upper case 120, thereby covering the fastening member 130. An adhesive material may be applied to a lower surface of the cover 140 so that the cover 140 may be attached to the upper surface of the upper case 120.

The connection portion 112, the hole 122, and the fastening member 130 may be one or more in number.

The electronic apparatus 100 may further include an indicator 124 and a cable 152. A shape output by the indicator 124 may be varied according to an electronic signal supplied by the electronic circuit board 150. The electronic signal may be transmitted from the electronic circuit board 150 to the indicator 124 through the cable 152.

The indicator 124 may include an information output member such as a liquid crystal display (LCD), a light emitting diode (LED), and the like.

The cover 140 may include a through portion 142 formed on a part. The through portion 142 may be an empty space or a transparent member. That is, the empty space or the transparent member may be disposed at the part of the cover 140. When the cover 140 is attached to the upper case 120, the indicator 124 may be exposed to the outside through the through portion 142.

The cover 140 may include various design patterns formed on a surface. A plurality of the covers 140 may be provided. In this case, the plurality of covers 140 may be replaced and attached to the upper surface of the upper case 120 by a user of the electronic apparatus 100.

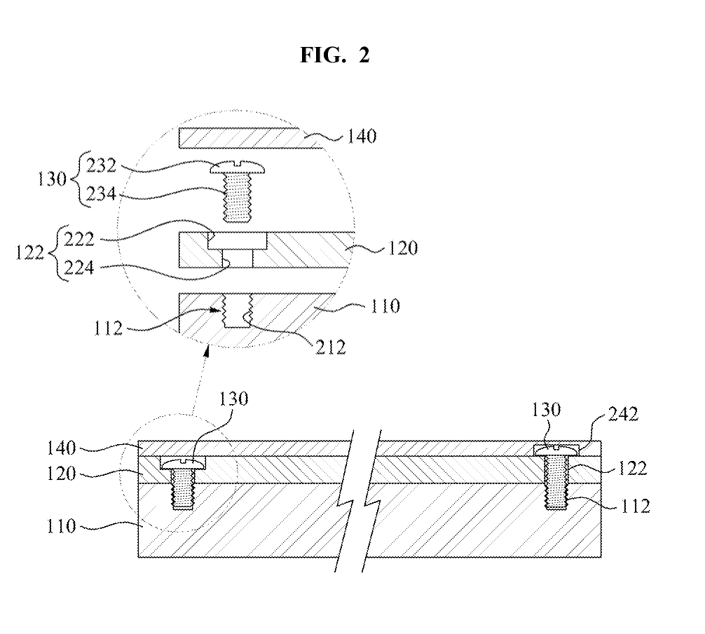

FIG. 2 is a diagram illustrating a connection system of a fastening member 130 according to the embodiment of the present invention.

FIG. 2 is a sectional view of the electronic apparatus 100.

The fastening member 130 may be a bolt. In this case, the fastening member 130 may include a head 232 for turning the bolt and a body 234 formed with a screw thread. In addition, a boss portion 212 may be formed on a side surface of the connection portion 112 to be engaged with the screw thread.

Two methods may be used to receive the head 232 of the fastening member 130.

First, the upper case 120 may include a head receiving portion 222 and a body passing portion 224, so as to receive the head 232 of the fastening member 130. The head receiving portion 222 may be in the form of a hole having a proper size for receiving the head 232. The body passing portion 224 may be in the form of a hole having a size allowing passage of only the body 234 but not the head 232.

Second, an empty space 242 may be formed at a lower surface of the cover 140 to receive the head 232 of the fastening member 130. Here, the hole 122 of the upper case 120 may be in a size allowing passage of the body 234 but not the head 232. The empty space 242 may have a proper size for receiving the head 232 of the fastening member 130.

In the present embodiment, the bolt is suggested only as an example of the fastening member 130. That is, various types such as a wedge type may be used as the fastening member 130.

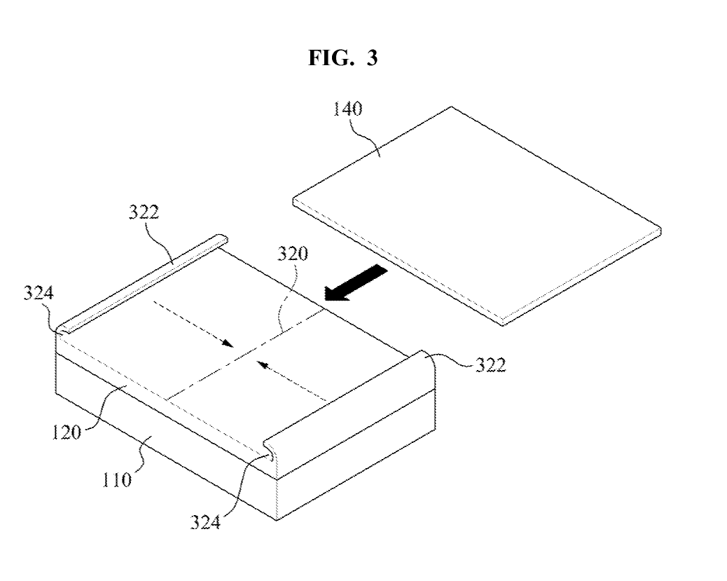

FIG. 3 is a diagram illustrating a guide of a cover according to the embodiment of the present invention.

The upper case 120 may include a guide portion 322 bent at a predetermined angle from a corner of the upper case 120 toward a center 320 of the upper case 120. A plurality of the guide portions 322 may be provided.

The cover 140 may be slid into a groove 324 formed by bending the guide portion 322 and thereby attached to the upper surface of the upper case 120.

Although the cover 140 is attached to the upper surface of the upper case 120 in the sliding manner in the present embodiment, this is only by way of example. Therefore, attachment of the cover 140 may be achieved by various means such as direct fastening.

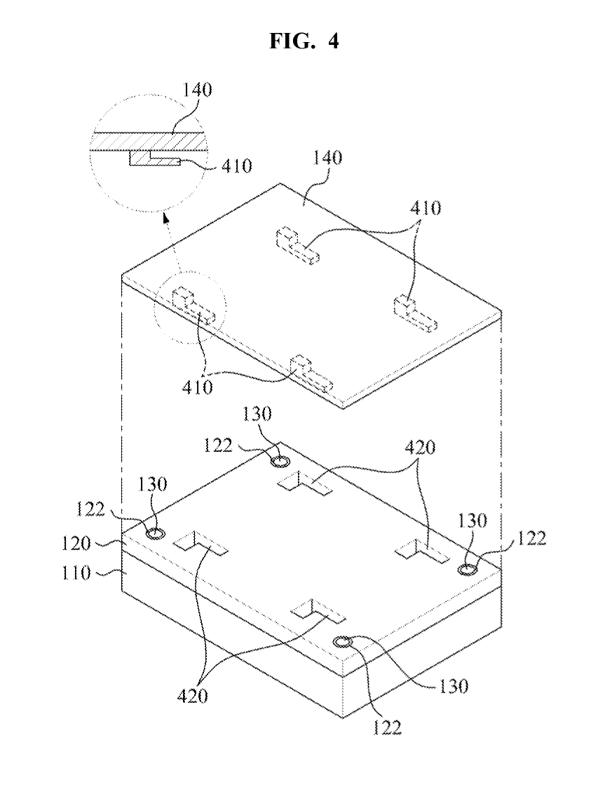

FIG. 4 is a diagram illustrating a fastening protrusion of a cover according to the embodiment of the present invention.

The cover 140 may include a fastening protrusion 410 formed on the lower surface. The fastening protrusion 410 may have an L-shape. That is, the fastening protrusion 410 may protrude from the lower surface of the cover 140 and bend at the right angle. The fastening protrusion 410 may be bent to be horizontal to the lower surface of the cover 140.

The upper case 120 may include a fastening hole 420 to insert the fastening protrusion 410. The fastening hole 420 may be formed on the surface of the upper case 120 in an L-shape.

The fastening protrusion 410 may be inserted in the fastening hole 420. The fastening protrusion 410 inserted in the fastening hole 420 may be slid along the fastening hole 420 and thereby fixed in the upper case 120. As a portion of the fastening protrusion 410 horizontal to the lower surface of the cover 140 comes into close contact with the lower surface of the upper case 120, the cover 140 may be attached to the upper case 120. A portion of the fastening protrusion 410 vertical to the lower surface of the cover 140 may have a proper length according to thickness of the upper case 120 such that the portion of the fastening protrusion 410 horizontal to the lower surface of the cover 140 may closely contact the lower surface of the upper case 120.

A plurality of the fastening protrusions 410 and a plurality of the fastening holes 420 may be provided. In FIG. 4, for example, four fastening protrusions 410 and four fastening holes 420 are illustrated. The fastening protrusions 410 may be formed on the lower surface of the cover 140 in a random number appropriate for attaching the cover 140 to the upper case 120. Corresponding to the fastening protrusions 410, the fastening holes 420 may be formed on the upper case 120.

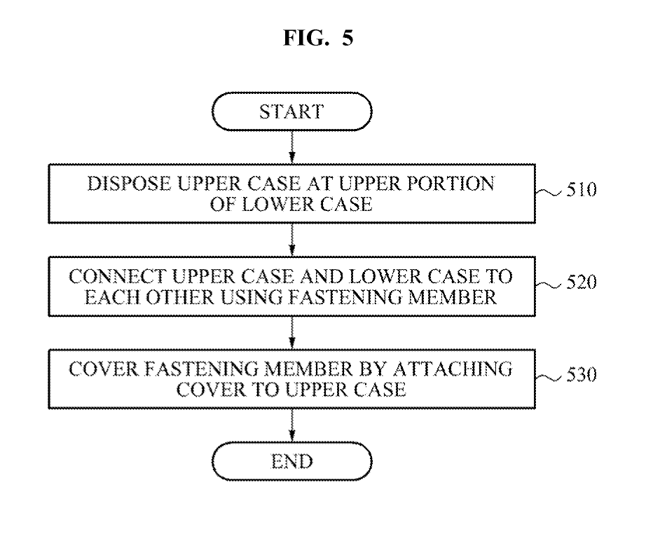

FIG. 5 is a flowchart illustrating a manufacture method of an electronic apparatus, according to an embodiment of the present invention.

In operation 510, an upper case that protects an electronic circuit board is disposed on an upper part of a lower case that protects the electronic circuit board.

In operation 520, a fastening member is passed through a hole formed at the upper case and fastened to a connection portion formed at the lower case. Accordingly, the upper case and the lower case are connected to each other.

In operation 530, a cover is attached to an upper surface of the upper case to thereby cover the fastening member.

The operations 510, 520, and 530 are performed from a ceiling surface of the electronic apparatus. For example, a force to connect the fastening member to the lower case is applied in a direction from the ceiling surface to a bottom surface. Therefore, the operations 510, 520, and 530 may be performed in a state where the electronic apparatus or the lower case is placed on a base floor. For example, the operations 510, 520, and 530 may be performed while the lower case is being transferred on a conveyer belt. That is, the electronic apparatus or the lower case may be stably placed on the base floor without being turned over during the manufacturing.

Technical features already illustrated with reference to FIGS. 1 to 4 may be applied to the present embodiment and therefore will not be described again.

The above-described embodiments of the present invention may be recorded in non-transitory computer-readable media including program instructions to implement various operations embodied by a computer. The media may also include, alone or in combination with the program instructions, data files, data structures, and the like. The program instructions recorded on the media may be those specially designed and constructed for the purposes of the embodiments, or they may be of the kind well-known and available to those having skill in the computer software arts. Examples of non-transitory computer-readable media include magnetic media such as hard disks, floppy disks, and magnetic tape; optical media such as CD ROM disks and DVDs; magneto-optical media such as optical discs; and hardware devices that are specially configured to store and perform program instructions, such as read-only memory (ROM), random access memory (RAM), flash memory, and the like. Examples of program instructions include both machine code, such as produced by a compiler, and files containing higher level code that may be executed by the computer using an interpreter. The described hardware devices may be configured to act as one or more software modules in order to perform the operations of the above-described embodiments of the present invention, or vice versa.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. An electronic apparatus comprising:
a lower case to protect an electronic circuit board;
an upper case to protect the electronic circuit board;
a fastening member to connect the upper case and the lower case to each other by passing through a hole formed at the upper case and being fastened to a connection portion of the lower case; and
a cover attached to an upper surface of the upper case to cover the fastening member.

2. The electronic apparatus of claim 1, wherein the cover comprises an empty space formed at a lower surface to receive a head of the fastening member.

3. The electronic apparatus of claim 1, wherein
the cover comprises a fastening protrusion formed on a lower surface,
the upper case comprises a fastening hole for insertion of the fastening protrusion, and
the fastening member is inserted in and slid along the fastening hole, thereby being fixed in the upper case.

4. The electronic apparatus of claim 1, wherein
the upper case comprises an indicator disposed on a surface to output different shapes according to an electronic signal supplied from the electronic circuit board,
the cover comprises an empty space or a transparent portion formed on a part of the cover, and
the indicator is exposed through the empty space or the transparent portion of the cover when the cover is attached to the upper case.

5. The electronic apparatus of claim 1, wherein a plurality of the covers are attached to the upper surface of the upper case in a replaceable manner.
